(19) United States
(12) Patent Application Publication
(10) Pub. No.: US 2014/0093995 A1
(43) Pub. Date: Apr. 3, 2014

(54) Method of Hybrid Stacked Chip for a Solar Cell

(71) Applicant: Chang Gung University, Taoyuan County (TW)

(72) Inventors: Liann-Be Chang, Taoyuan County (TW); Yu-Lin Lee, Tainan City (TW)

(73) Assignee: Chang Gung University, Taoyuan County (TW)

(21) Appl. No.: 14/089,864

(22) Filed: Nov. 26, 2013

Related U.S. Application Data
(63) Continuation-in-part of application No. 11/746,698, filed on May 10, 2007, now abandoned.

(51) Int. Cl. H01L 31/05

(52) U.S. Cl. CPC H01L 31/0508
USPC 438/74

(57) ABSTRACT

A method of hybrid stacked Chip for a solar cell onto which semiconductor layers of different materials is provided by stacking tunnel layer and bumps in order to solve the problem of lattices mismatch between the layers for further increasing of the efficiency of solar cell. Electric charges (i.e., current) generated by respective solar cells can be outputted by means of contacts. Further total power P is defined by a summation of powers of respective solar cells, i.e., V1I1+V2I2+ . . . VnIn. This is a great increase in comparison with the power of conventional solar cells connected in series.

### BACKGROUND OF THE INVENTION

1. Field of the Invention

The invention relates to a method and technology of a hybrid stacked chip for a solar cell and, particularly, to that of manufacturing a simple and higher efficient solar cell.

2. Description of Related Art

As shown in FIG. 4A, the solar cell comprises a substrate 60 of silicon (Si), germanium (Ge), or Si/Ge. On the substrate 60, a P-N junction semiconductor layer 61, such as Si/SiGe, that may absorb a long wavelength (e.g. infrared rays), is formed. It has an efficiency of around only 15%.

A compound solar cell is formed by a compound semiconductor on a substrate to absorb a medium wavelength solar spectrum. Owing to a direct bandgap, it has higher efficiency and absorbs the correspondent wavelength of around 25%. As shown in FIG. 4B, the solar cell comprises a substrate 70 of GaAs, AlGaAs, InGaP or GaP. On the substrate 70, a P-N junction semiconductor layer 71, such as GaAs/AlGaAs, GaAs/InGaP, GaP/GaP, GaAs/AlInGaP, and GaAs/AlGaAs . . . etc., that may absorb a medium wavelength (e.g. visible rays), is formed.

As shown in FIG. 4C, the solar cell comprises a substrate 81 of Al₂O₃ sapphire, silicon carbide, or ZnO. On the substrate 81, a P-N junction semiconductor layer 80, such as GaN/AlGaN, GaN/InGaN and InGaN/AlGaN that may absorb a short wavelength (e.g. ultraviolet rays), is formed.

However, each solar cell mentioned above may absorb only the correspondent long wavelength (as shown in FIG. 4A), medium wavelength (as shown in FIG. 4B), or the short wavelength (as shown in FIG. 4C), respectively.

Thus, recently, a tandem cell is provided in which materials of different bandgaps are stacked into the cell of multiple junctions.

As shown in FIG. 5A, the solar cell comprises a substrate 60 of Si, Ge, or Si/Ge. On the substrate 60, a P-N junction semiconductor layer 61, such as Si and SiGe, that may absorb the long wavelength is stacked so as to absorb rays of light, and an tunnel junction 10 is formed on the P-N junction semiconductor layer 61. On the tunnel junction 10, a P-N junction semiconductor layer 71, such as GaAs, that may absorb the medium wavelength, is then stacked, and the tunnel junction 10 is formed on the P-N junction semiconductor layer 71. On the tunnel junction 10, a P-N junction semiconductor layer 72, such as AlGaAs and InGaP, which may absorb the medium wavelength, is then stacked.

As shown in FIG. 5B, the solar cell comprises a substrate 70 of GaAs, As, or GaP. On the substrate 70, a P-N junction semiconductor layer 71, such as GaAs, that may absorb the medium wavelength, is then stacked, and the tunnel junction 10 is formed on the P-N junction semiconductor layer 71. On the tunnel junction 10, a P-N junction semiconductor layer 72, such as AlGaAs and InGaP, which may absorb the medium wavelength, is then stacked.

However, Si/SiGe, GaN/AlGaN, and GaAs/AlGaAs used for the semiconductors are quite different, for achieving a high-quality epitaxial film, a small lattice mismatch value of less than 5% is universally desired. So the semiconductor epitaxy when formed is easily polluted with each other.

A typical Battery is comprised of a plurality solar cells connected in series. Thus, its total voltage is a summation of respective solar cells (i.e., V1+V2+ . . . Vn). Also, the solar cell having the smallest current will be chosen as the current of the battery for the sake of current match. That is, the current is (I1, I2 . . . In)ₘᵢₙ. Power P is thus (V1+V2+ . . . Vn)*(I1, I2 . . . In)ₘᵢₙ. Disadvantageously, power P is low.

Consequently, because of the technical defects of described above, the present invention was developed, which can effectively improve the defects described above.

### SUMMARY OF THE INVENTION

The invention relates to a method of a hybrid stacked Chip for a solar cell, comprising:

step 1 of forming a solar cell with at least one pair of P-N junction semiconductor layers and making each P-N junction semiconductor layer to absorb various wavelengths of solar spectrum by corresponding to different materials;

step 2 of forming another solar cell with at least one P-N junction semiconductor layer of which the series of materials are different from step 1; and

step 3 of stacking each of the P-N junction semiconductor layers described at step 1 and step 2 and stacking in order the P-N junction semiconductor layers from a long wavelength to a short wavelength.

Thus, in the invention to stack different series solar cells for increasing the efficiency of the solar cell and for solving the problem of lattice mismatch.

### BRIEF DESCRIPTION OF THE DRAWINGS

FIG. 1 is a flow chart of the invention;

FIG. 2A through FIG. 2D are schematic views illustrating embodiments of the invention;

FIG. 3 is a schematic view illustrating a preferred embodiment of the invention;

FIG. 4A through FIG. 4C are schematic views illustrating conventional embodiments; and

FIG. 5A and FIG. 5B are schematic views illustrating another conventional embodiment.

### DETAILED DESCRIPTION OF THE PREFERRED EMBODIMENTS

Now, the present invention will be described more specifically with reference to the following embodiments. It is to be noted that the following descriptions of preferred embodiments of the invention are presented herein for purpose of illustration and description only; and it is not intended to be exhaustive or to be limited to the precise form disclosed.

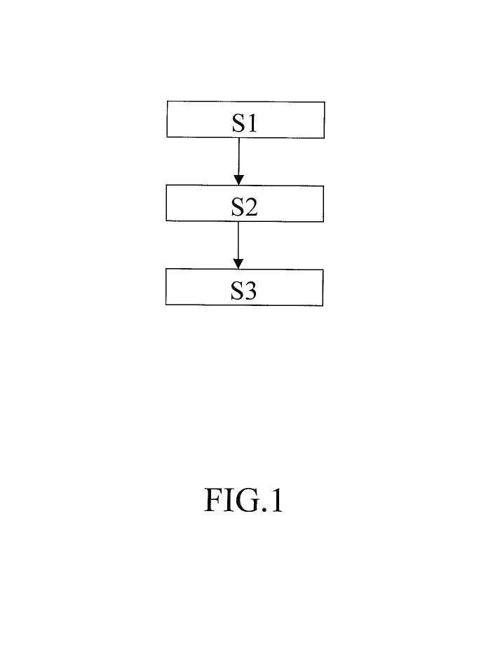

The invention relates to a method of a hybrid stacked chip for a solar cell and is used to stack a solar cell onto another solar cell, as shown in FIG. 1, the method comprising:

step S1 of forming a solar cell with at least one pair of P-N junction semiconductor layers and making each P-N junction semiconductor layer to absorb various wavelengths of solar spectrum by corresponding to different materials;

step S2 of forming another solar cell with at least one P-N junction semiconductor layer of which the series of materials are different from step S1; and

step 3 of stacking each of the P-N junction semiconductor layers described at step S1 and step S2 and stacking in order the P-N junction semiconductor layers from a long wavelength to a short wavelength.

In the following description, there are figures illustrating embodiments of the invention.

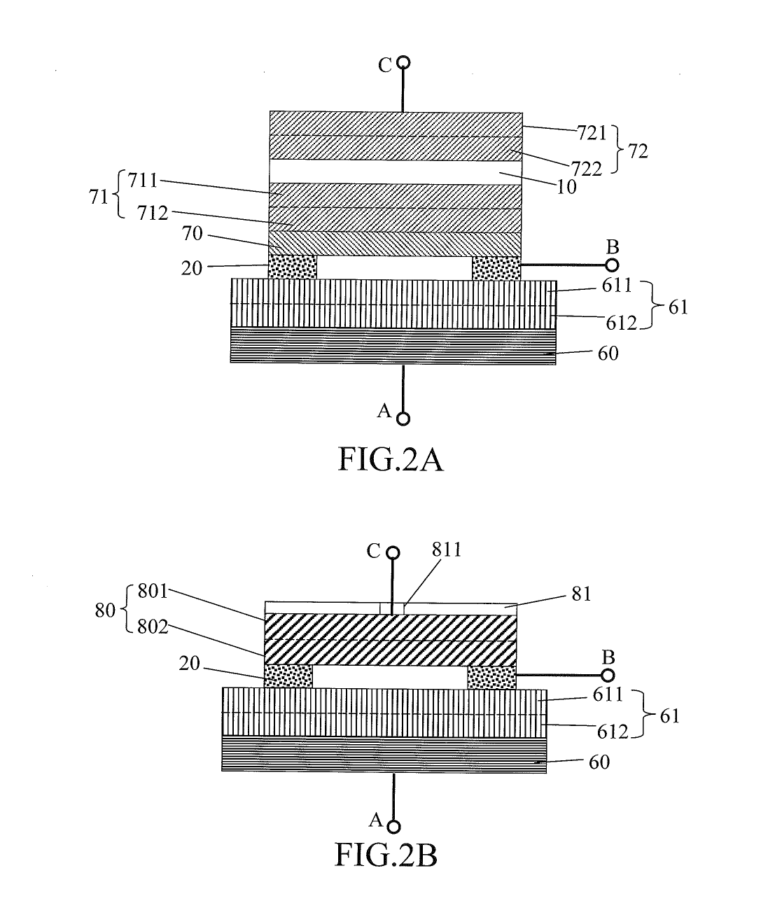

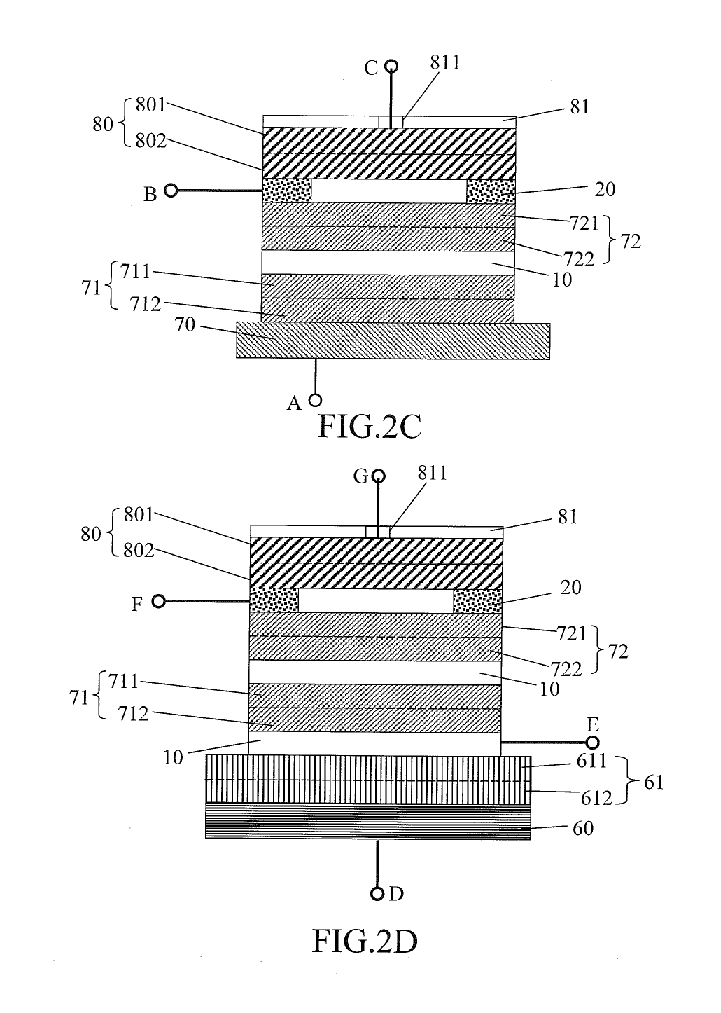

Refer to FIG. 2A illustrating:

formed a first solar cell including P-N junction semiconductor layers 61 of Si and Ge that may absorb a long wavelength, and its substrate 60 of Si, Ge, or Si/Ge;

formed a second solar cell including P-N junction semiconductor layers 71 and 72 of As, Ga, and P that may absorb a medium wavelength, and its substrate 70 of InP, GaAs, or GaP; and

the P-N junction semiconductor layers 71 and 72 of As, Ga, and P that may absorb the medium wavelength being stacked onto the P-N junction semiconductor layer 61 of Si and Ge that may absorb the long wavelength, in which the P-N junction semiconductor layers 71 and 72 of As, Ga, and P that may absorb the medium wavelength lie on the substrate 70 of InP, GaAs or GaP.

The P-N junction semiconductor layers 61, 71 and 72 comprise layers of materials 611, 612, 711, 712, and 721, 722 respectively, that are doped to form n-type and p-type semiconductors. In this manner, the p/n or n/p junctions are formed in each of the P-N junction semiconductor layers 61, 71 and 72.

The series of materials of the P-N junction semiconductor layer 61 of Si and Ge that may absorb the long wavelength and those of the P-N junction semiconductor layers 71 and 72 of As, Ga, and P that may absorb the medium wavelength are different so that connection bumps 20 may be formed between the first and second solar cells, and the first and second solar cells of different materials are combined together. A first contact A is connected to a bottom of the substrate 60. A second contact B is connected to the connection bumps 20. A third contact C is connected to a top of the P-N junction semiconductor layers 72. As such, the P-N junction semiconductor layers 61, 71 and 72 are coupled together by the first, second, and third contacts A, B, and C to form a three-terminal solar cell and electric charges generated by light impinging on the P-N junction semiconductor layers 61, 71 and 72 can be respectively outputted.

Refer to FIG. 2B illustrating:

formed a first solar cell including a P-N junction semiconductor layers 61 of Si and Ge that may absorb the long wavelength, and its substrate 60 of Si, Ge, or Si/Ge;

formed a second solar cell including a P-N junction semiconductor layer 80 of Ga, In, Al and N that may absorb the short wavelength, and its transparent substrate 81 of Al₂O₃ sapphire, silicon carbide, or ZnO; and, the P-N junction semiconductor layer 80 of Ga, In, Al and N that may absorb the short wavelength being stacked onto the P-N junction semiconductor layers 61 of Si and Ge that may absorb the long wavelength, in which the transparent substrate 81 of Al₂O₃ sapphire, silicon carbide, or ZnO lies on the P-N junction semiconductor layer 80 of Ga, In, Al and N that may absorb the short wavelength.

The P-N junction semiconductor layers 61 and 80 comprise layers of materials 611, 612 and 801, 802 respectively, that are doped to form n-type and p-type semiconductors.

In this manner, the p/n or n/p junctions are formed in each of the P-N junction semiconductor layers 61 and 80.

The series of materials of the P-N junction semiconductor layers 61 of Si and Ge that may absorb the long wavelength and those of the P-N junction semiconductor layer 80 of Ga, In, Al and N that may absorb the short wavelength are different so that connection bumps 20 may be formed between the first and second solar cells, and the first and second solar cells of different materials are combined together.

A first contact A is connected to a bottom of the substrate 60. A second contact B is connected to the connection bumps 20. A third contact C is connected to a top of the P-N junction semiconductor layer 80. As such, the P-N junction semiconductor layers 61 and 80 are coupled together by the first, second, and third contacts A, B, and C to form a three-terminal solar cell and electric charges generated by light impinging on the P-N junction semiconductor layers 61 and 80 can be respectively outputted.

An aperture 811 is formed in the transparent substrate 81 and the third contact C is connected to the P-N junction semiconductor layer 80 so that electric charges generated by light impinging on P-N junction semiconductor layer 80 can be outputted through the aperture 811.

Refer to FIG. 2C illustrating:

formed a first solar cell including P-N junction semiconductor layers 71 and 72 of As, Ga, and P that may absorb the medium wavelength, and its substrate 70 of InP, GaAs or GaP;

formed a second solar cell including a P-N junction semiconductor layer 80 of Ga, In, Al and N that may absorb the long wavelength, and its transparent substrate 81 of Al₂O₃ sapphire, silicon carbide, or ZnO; and

the P-N junction semiconductor layer 80 that may absorb the short wavelength being stacked onto the P-N junction semiconductor layers 71 and 72 of As, Ga, and P that may absorb the medium wavelength, in which the transparent substrate 81 of Al₂O₃ sapphire, silicon carbide, or ZnO lies on the P-N junction semiconductor layer 80 of Ga, In, Al and N that may absorb the short wavelength.

The P-N junction semiconductor layers 71, 72 and 80 comprise layers of materials 711, 712, 721, 722 and 801, 802 respectively, that are doped to form n-type and p-type semiconductors. In this manner, the p/n or n/p junctions are formed in each of the P-N junction semiconductor layers 71, 72 and 80.

The series of materials of the P-N junction semiconductor layers 71 and 72 of As, Ga, and P that may absorb the medium wavelength and those of the P-N junction semiconductor layer 80 of Ga, In, Al and N that may absorb short the wavelength are different so that connection bumps 20 may be formed between the first and second solar cells, and the first and second solar cells of different materials are combined together.

A first contact A is connected to a bottom of the substrate 70. A second contact B is connected to the connection bumps 20. A third contact C is connected to a top of the P-N junction semiconductor layer 80. As such, the P-N junction semiconductor layers 71, 72 and 80 are coupled together by the first, second, and third contacts A, B, and C to form a three-terminal solar cell and electric charges generated by light impinging on the P-N junction semiconductor layers 71, 72 and 80 can be respectively outputted.

An aperture 811 is formed in the transparent substrate 81 and the third contact C is connected to the P-N junction semiconductor layer 80 so that electric charges generated by light impinging on the P-N junction semiconductor layer 80 can be outputted through the aperture 811.

Refer to FIG. 2D illustrating:

a first solar cell including substrate 60 of Si, Ge, or Si/Ge on which P-N junction semiconductor layers 61, such as Si and SiGe, that may absorb the long wavelength is stacked; a second solar cell including P-N junction semiconductor layers 71 and 72 of As, Ga, and P that may absorb a medium wavelength, and the substrate 70 of InP, GaAs, or GaP; a tunnel junction 10 being formed on the layer 61, and a P-N junction semiconductor layers 71, such as GaAs, that may absorb the medium wavelength being formed on the tunnel junction 10; a tunnel junction 10 being again formed on the layer 71, and a P-N junction semiconductor layer 72, such as AlGaAs and InGaP, that may absorb the medium wavelength being stacked being formed on the tunnel junction 10;

formed third solar cell including a P-N junction semiconductor layer 80 of Ga, In, Al an N, that may absorb the short wavelength, and its transparent substrate 81 of Al₂O₃ sapphire, silicon carbide, or ZnO; and

the P-N junction semiconductor layer 80 of Ga, In, Al and N that may absorb the short wavelength being stacked onto the P-N junction semiconductor layer 72 that may absorb the medium wavelength.

The P-N junction semiconductor layers 61, 71, 72 and 80 comprise layers of materials 611, 612, 711, 712, 721, 722 and 801, 802 respectively, that are doped to form n-type and p-type semiconductors. In this manner, the p/n or n/p junctions are formed in each of the P-N junction semiconductor layers 61, 71, 72 and 80.

The series of materials of the P-N junction semiconductor layer 80 of Ga, In, Al and N that may absorb the short wavelength and those of the P-N junction semiconductor layers 72 that may absorb the medium wavelength are different so that connection bumps 20 may be formed between the second and third solar cells, and the second and third solar cells of different materials are combined together.

A fourth contact D is connected to a bottom of the substrate 60. A fifth contact E is connected to the tunnel junction 10. A sixth contact F is connected to the connection bumps 20. A seventh contact G is connected to a top of the P-N junction semiconductor layer 80. As such, the P-N junction semiconductor layers 61, 71, 72 and 80 are coupled together by the fourth, fifth, sixth, and seventh contacts D, E, F, and G to form a four-terminal solar cell and electric charges generated by light impinging on the P-N junction semiconductor layers 61, 71, 72 and 80 can be respectively outputted.

An aperture 811 is formed in the transparent substrate 81 and the seventh contact G is connected to the P-N junction semiconductor layer 80 so that electric charges generated by light impinging on the P-N junction semiconductor layer 80 can be outputted through the aperture 811.

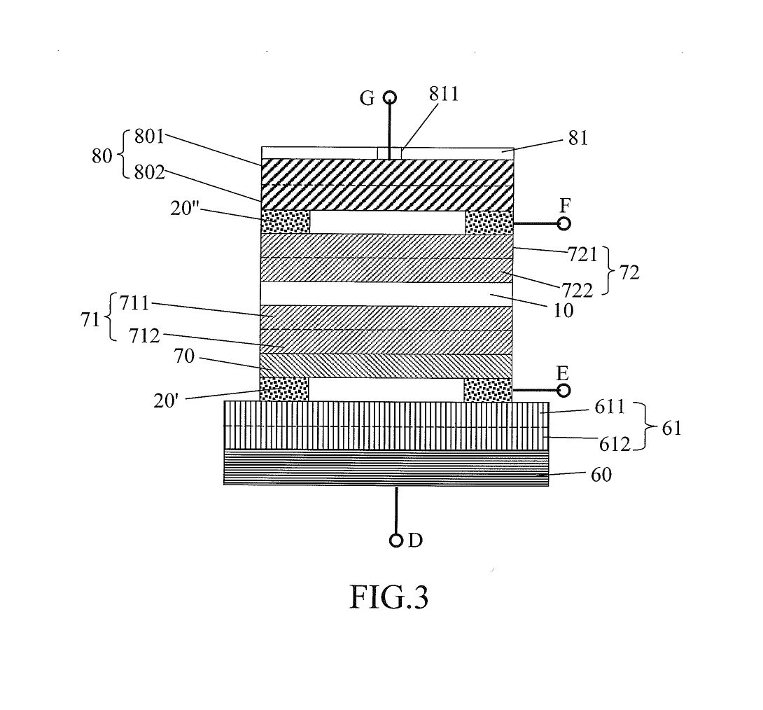

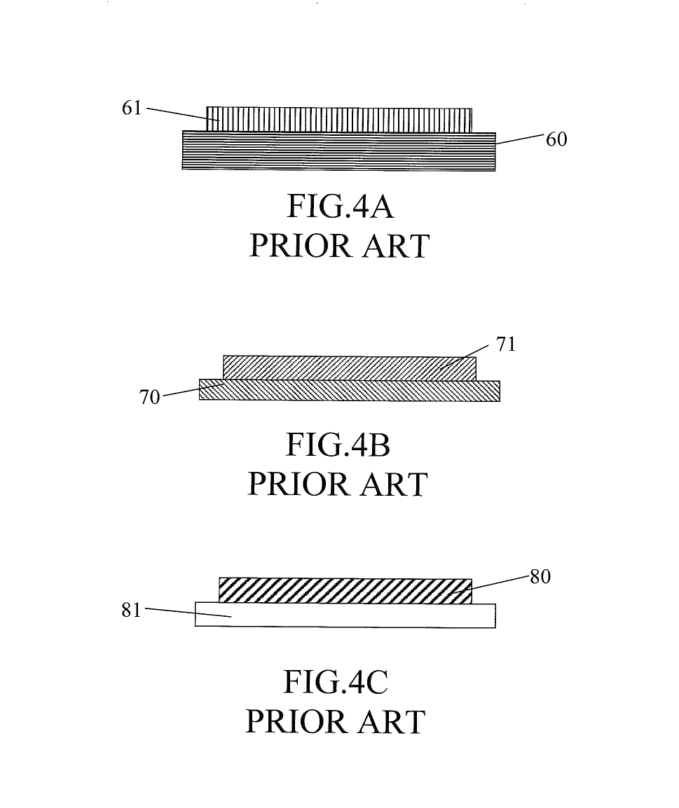

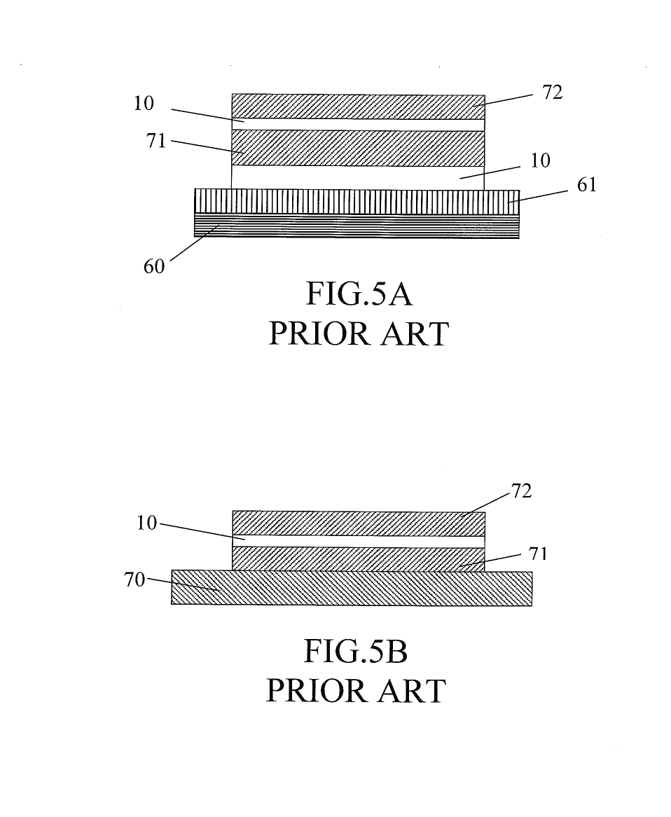

Refer to FIG. 3 illustrating:

formed first solar cell including P-N junction semiconductor layers 61 of Si and Ge, such as Si and Si/Ge, that may absorb the long wavelength;

formed second solar cell including P-N junction semiconductor layers 71 and 72 of As, Ga, and P, such as GaAs/AlGaAs, GaAs/InGaP, GaP/GaP, GaAs/AlIn GaP, and GaAs/AlGaAs . . . etc., that may absorb the medium wavelength;

formed third solar cell including a P-N junction semiconductor layer 80 of GaN/AlGaN, GaN/InGaN and InGaN/AlGaN, that may absorb the short wavelength, and its transparent substrate 81 of Al₂O₃ sapphire, silicon carbide, or ZnO; and

the P-N junction semiconductor layers 71 and 72 that may absorb the medium wavelength and the P-N junction semiconductor layer 80 that may absorb the short wavelength being stacked in order onto the P-N junction semiconductor layers 61 of Si and Ge that may absorb the long wavelength.

The P-N junction semiconductor layers 61, 71, 72 and 80 comprise layers of materials 611, 612, 711, 712, 721, 722 and 801, 802 respectively, that are doped to form n-type and p-type semiconductors. In this manner, the p/n or n/p junctions are formed in each of the P-N junction semiconductor layers 61, 71, 72 and 80.

The series of materials of the P-N junction semiconductor layers 61 of Si and Ge that may absorb the long wavelength, those of the P-N junction semiconductor layers 71 and 72 of As, Ga, and P that may absorb the medium wavelength, and those of the P-N junction semiconductor layers of Ga, In, Al and N that may absorb the short wavelength are different so that first connection bumps 20′ may be formed between the first and second solar cells, second connection bumps 20″ may be formed between the second and third solar cells, and the P-N junction semiconductor layers of different materials are combined together.

A fourth contact D is connected to a bottom of the substrate 60. A fifth contact E is connected to the first connection bumps 20′. A sixth contact F is connected to the second connection bumps 20″. A seventh contact G is connected to a top of the P-N junction semiconductor layer 80. As such, the P-N junction semiconductor layers 61, 71, 72 and 80 are coupled together by the fourth, fifth, sixth, and seventh contacts D,E, F, and G to form a four-terminal solar cell and electric charges generated by light impinging on the P-N junction semiconductor layers 61, 71, 72 and 80 can be respectively outputted.

An aperture 811 is formed in the transparent substrate 81 and the seventh contact G is connected to the P-N junction semiconductor layer 80 so that electric charges generated by light impinging on the P-N junction semiconductor layer 80 can be outputted through the aperture 811.

In FIGS. 2A through 2D and FIG. 3A through 3C, it is more convenient and easier to be electrically conductive to connect a chip with the connection bumps 20 in the Stack-Chip technology than connecting a conventional solar cell with a tunnel junction. Thus, the materials that may absorb the long, medium, and short wavelengths are better in efficiency and solve the problem of lattice mismatch.

It is envisaged by the invention that electric charges (i.e., current) generated by respective solar cells (e.g., at least two solar cells such as 2, 3, 4, or 5) can be outputted by means of contacts. Further total power P is defined by a summation of powers of respective solar cells, i.e., V1I1+V2I2+ . . . VnIn. This is a great increase in comparison with the power of conventional solar cells connected in series, i.e., (V1+V2+ . . . Vn)*(I1, I2 . . . In)ₘᵢₙ. Further, in the invention, a lens (not shown) may be arranged on the solar cell to concentrate the beams of light so that the area of the solar cell under the lens may be reduced. Further, the cost of the solar cell according to the invention may be down.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims that are to be accorded with the broadest interpretation so as to encompass all such modifications and similar structures.

What is claimed is:

1. A method comprising:
stacking at least two solar cells each including a plurality of P-N junction semiconductor layers formed on a substrate, each of the solar cells being capable of absorbing light of different wavelengths, a plurality of spaced connection bumps between the solar cells, and a plurality of tunnel junction layers formed between the solar cells; and
connecting a plurality of contacts to the at least two solar cells so as to respectively output electric charged generated by the at least two solar cells.

2. The method according to claim 1, wherein a plurality of p/n or n/p junctions are formed in each of the P-N junction semiconductor layers.

3. The method according to claim 1,
wherein each of the at least two solar cells include a first solar cell including P-N junction semiconductor layers formed on a substrate, with the first solar cell absorbing a first wavelength of light; and a second solar cell including a P-N junction semiconductor layer formed on a substrate, with the second solar cell absorbing a second wavelength of light different from the first wavelength;
wherein the stacking includes the formed second solar cell on the formed first solar cell, and a plurality of spaced connection bumps between the first and second solar cells; and
wherein a first contact of the contacts is connected to a bottom of the first solar cell, a second contact of the contacts is connected to the connection bumps, a third contact of the contacts is connected to a top of the second solar cell so that the first and second solar cells are coupled together by the first, second, and third contacts to form a three-terminal solar cell and electric charges generated by light impinging on the first and second solar cells can be outputted.

4. The method according to claim 3, wherein the p/n or nip junction are formed in each of the P-N junction semiconductor layers.

5. The method according to claim 3, wherein the P-N junction semiconductor layer of the first solar cell is formed of Si, Ge or SiGe capable of absorbing light of a long wavelength.

6. The method according to claim 3, wherein the P-N junction semiconductor layer of one of the first and second solar cells is formed of Al, Ga, In, As and P capable of absorbing light of medium wavelength.

7. The method according to claim 3, wherein the first wavelength is greater than the second wavelength.

8. The method according to claim 3, wherein the P-N junction semiconductor layer of the first solar cell is formed of Si and Ge capable of absorbing light of a long wavelength, and the P-N junction semiconductor layer of the second solar cell is formed of Ga, In, Al and N capable of absorbing light of a short wavelength.

9. The method according to claim 8, wherein the substrate of the second solar cell is formed with an aperture so that electric charges generated by light impinging on the second solar cell can be outputted through the aperture.

10. The method according to claim 3, wherein the P-N junction semiconductor layer of the first solar cell is formed of As and P capable of absorbing light of a medium wavelength, and the P-N junction semiconductor layer of the second layer is formed of Ga, In, Al and N capable of absorbing light of a short wavelength.

11. The method according to claim 10, wherein the substrate of the second solar cell is formed with an aperture so that electric charges generated by light impinging on the second solar cell can be outputted through the aperture.

12. The method according to claim 7, wherein forming the P-N junction semiconductor layer of the second solar cell comprises forming the P-N junction semiconductor layer as two layers and forming a tunnel junction layer between the two layers in order to increase conductivity of the two layers connected in series.

13. The method according to claim 12, wherein providing the first and second connection bumps comprises forming the first and second connection bumps between the P-N junction semiconductor layer of the first solar cell and the substrate of the second solar cell.

14. The method according to claim 1,
wherein each of the at least two solar cells include a first solar cell including P-N junction semiconductor layers formed on a substrate, with the first solar cell capable of absorbing light of a first wavelength, and a second solar cell including a P-N junction semiconductor layer formed on a substrate, with the second solar cell capable of absorbing light of a second wavelength different from the first wavelength;
wherein the stacking includes a third solar cell having a P-N junction semiconductor layer on a substrate with the third solar cell capable of absorbing light of a third wavelength different from the first and second wavelengths, a second solar cell formed on the first solar cell, and a third solar cell formed on the second solar cell; and
wherein the stacking further includes a plurality of first and second spaced connection bumps between the first, second and third solar cells, and a tunnel junction layer formed between the first, second and third solar cells.

15. The method according to claim 14, wherein the p/n or n/p junction are formed in each of the P-N junction semiconductor layers.

16. The method according to claim 14,
wherein forming the first solar cell comprises forming the P-N junction semiconductor layer of the first solar cell for absorbing light of a long wavelength; wherein forming the second solar cell comprises forming the P-N junction semiconductor layer of the second solar cell for absorbing light of a medium wavelength less than the long wavelength; and
wherein forming the third solar cell comprises forming the P-N junction semiconductor layer of the third solar cell for absorbing light of a short wavelength less than the medium wavelength.

17. The method according to claim 14 wherein providing the first and second connection bumps comprises a plurality of first connection bumps formed between the first and second solar cells, and a plurality of second connection bumps formed between the second and third solar cells; and
wherein a fourth contact of the contacts is connected to a bottom of the first solar cell, a fifth contact is connected to the first connection bumps, a sixth contact of the contacts is connected to the second connection bumps, a seventh contact of the contact is connected to a top of the third solar cell to form a four-terminal solar cell so that electric charges generated by light impinging on the first, second and third solar cells can be respectively outputted by means of the connection of the fourth, fifth, sixth, and seventh contacts.

18. The method according to claim 14,
wherein providing the tunnel junction and the connection bumps comprises a plurality of tunnel junctions formed between the first and second solar cells, and a plurality of connection bumps formed between the second and third solar cells; and
wherein a fourth contact of the contacts is connected to a bottom of the first solar cell, a fifth contact is connected to the tunnel junctions, a sixth contact of the contacts is connected to the connection bumps, a seventh contact of the contact is connected to a top of the third solar cell to form a four-terminal solar cell so that electric charges generated by light impinging on the first, second and third solar cells can be respectively outputted by means of the connection of the fourth, fifth, sixth, and seventh contacts.

19. The method according to claim 3 wherein providing the first and second connection bumps comprises forming the first and second connection bumps between the P-N junction semiconductor layers of the first and second solar cells.
